(19) United States
(12) Patent Application Publication
(10) Pub. No.: US 2002/0015454 A1
(43) Pub. Date: Feb. 7, 2002

(54) Receiver, method, system and telephone for improving the detection of transmission errors

(75) Inventor: Ahmed Nabil Charkani, Le Mans (FR)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/891,429

(22) Filed: Jun. 26, 2001

(30) Foreign Application Priority Data
Jun. 30, 2000 (FR) 0008541

(51) Int. Cl. H04L 27/06; H04L 27/14; H03K 9/00; H04L 27/22

(52) U.S. Cl. 375/316

(57) ABSTRACT

The invention relates to an error detection method and system which are even applicable in poor transmission conditions. It comprises means for detecting a transmission error in a data frame as a function of saturation information of the frequency band with which the frame is associated, and for deriving a bad-frame indication.

Application: digital telecommunication, mobile radio telephony.

The invention relates to the detection of transmission errors in digital transmission systems.

It finds numerous applications, notably in audio or video telecommunication systems using a transmission channel of which the transmission conditions (channel noise, interference, etc.) can be poor.

An error detection method is described in U.S. Pat. No. 5,706,396. This method is used for a digital audio signal encoded in frequency sub-bands. One or several parameters, which are characteristic of the signal and depend on the encoder used, are determined for each sub-band. The encoded signals as well as the parameters are protected by error correction codes before they are transmitted through the channel and subsequently received and decoded by a receiver. The error detection method consists of detecting sudden variations of the received parameters before the error correction codes realizing the channel decoding are applied. In this method, the signal is supposed to comprise an identifiable characteristic parameter which depends notably on the speech encoder used for the transmission.

It is an object of the invention to improve the detection of transmission errors independently of the speech encoder used. This detection may be performed on the decoded speech signal, which is not the case in the method quoted above. To this end, the invention provides a receiver and a method of receiving, in a given frequency band, a digital signal which is formatted in successive data frames, the receiver comprising means for:

filtering the received signal in at least one frequency sub-band,

detecting a saturation of the signal in one of the filtered frequency sub-bands and supplying saturation information of said sub-band,

detecting a transmission error in a received frame, referred to as current frame, as a function of the saturation information of the sub-band with which the current frame is associated for deriving a bad-frame indication.

The invention also provides a computer program which is programmed to perform the method according to the invention, as well as a system and a telephone comprising a receiver according to the invention.

These and other aspects of the invention are apparent from and will be elucidated, by way of non-limitative example, with reference to the embodiments described hereinafter.

In the drawings:

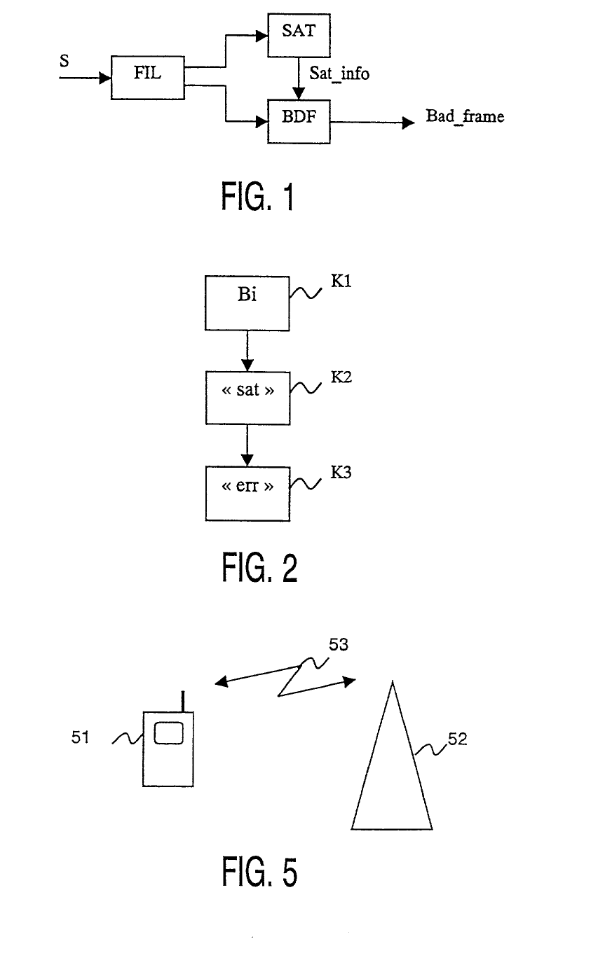

FIG. 1 is a block diagram showing an embodiment of the receiver according to the invention.

FIG. 2 is a block diagram illustrating a method according to the invention.

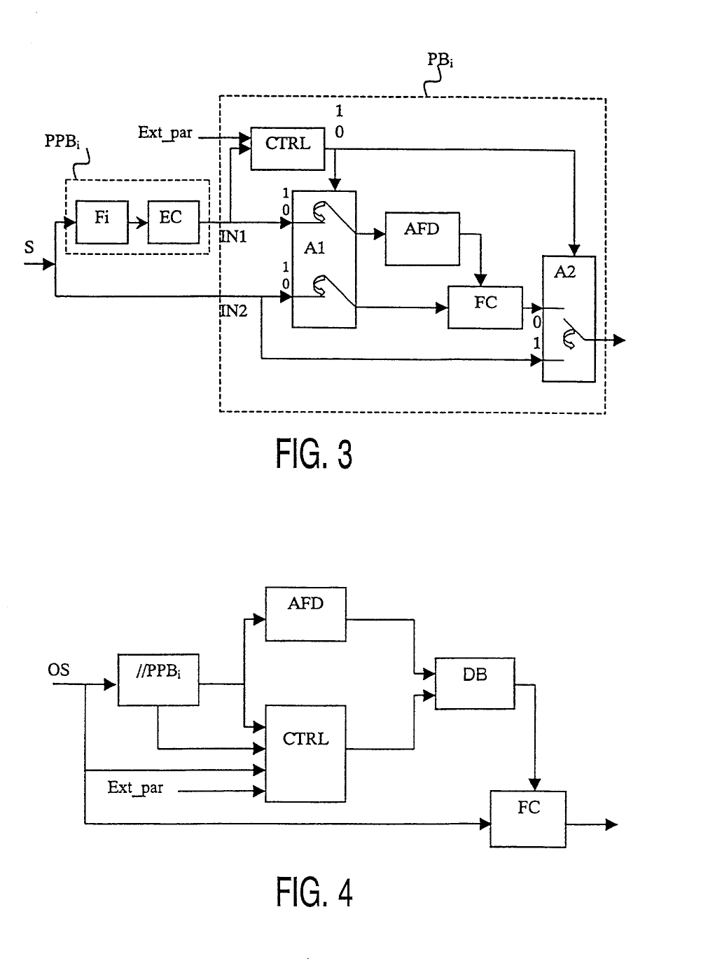

FIG. 3 is a block diagram showing a first embodiment of a receiver according to FIG. 1.

FIG. 4 is a block diagram showing a second embodiment of a receiver according to FIG. 1.

FIG. 5 is a diagram illustrating a system and a telephone according to the invention.

The receiver of FIG. 1 is intended to receive, within a given frequency band, a digital signal S which is formatted in successive data frames. The receiver comprises:

a filtering block FIL for filtering the received signal in at least one frequency sub-band,

a saturation detector SAT for detecting a saturation of the signal in one of the filtered frequency sub-bands and for supplying saturation information Sat_info of said sub-band,

a bad-frame detector BFD for detecting a transmission error in a received frame, referred to as current frame, as a function of the saturation information Sat_info of the sub-band with which the current frame is associated, and for deriving a bad-frame indication bad_frame.

The invention can be applied to advantage to a digital signal having (or from which can be extracted) a magnitude whose value has a probability which is higher than a fixed threshold to evolve, in the sequence of the frames, within a tolerance interval comprising at least a value taken during a preceding frame which has not been detected as a bad frame by the bad-frame detector BFD. In the case of such a signal, the bad-frame detector according to the invention may be provided, for example, for detecting an abnormal evolution of the value of the magnitude outside said tolerance interval. In accordance with a preferred embodiment of the invention, shown in FIGS. 3 and 4, said magnitude is representative of an energy of the received signal, which may be computed at the end of filtering or by one of the saturation or bad-frame detectors.

FIG. 2 is a simplified diagram illustrating a receiving method according to the invention, which method can be carried out by a receiver as shown in FIG. 1, in accordance with a software program comprising the appropriate instructions and stored in a memory of the receiver. The receiving method comprises the steps of

filtering K1 for filtering the received signal in at least one frequency sub-band,

saturation detection K2 for detecting a saturation of the signal in a sub-band and for supplying a saturation result “sat” of said sub-band,

bad-frame detection K3 for detecting a transmission error in a sub-band and for supplying an error signal “err” as a function of the saturation result of said sub-band.

According to the invention, the steps of saturation detection K2 and bad-frame detection K3 may be performed in parallel or in series. If they are performed in series, the saturation detection result is provided for activating or deactivating the bad-frame detection step. In the case of saturation of the sub-band, an error detection in the frames of the saturated band would not be reliable. If these steps are performed in parallel, a supplementary decision step is necessary for deciding, as a function of the result of the two detections, whether the current frame is effectively judged to be bad or not.

A first embodiment of the invention, referred to as the <<cascade mode>> comprises W series-arranged processing units, denoted PUᵢ, in which i is a positive index, with i≦W. For the sake of clarity, this is illustrated by way of a block diagram of a single processing unit PUᵢ in FIG. 3. The number W of units PUᵢ in series represents a number of sub-bands allowing a reconstitution of the passband of the received signal, and the index i represents the position of a unit in the cascade. Each unit PUᵢ is capable of detecting and possibly correcting transmission errors in the received signal. The output of a unit PUᵢ is connected to the input of the unit PUᵢ₊₁ until i=W−1. Each unit is constituted by a preprocessing block PPBᵢ and a processing block PBᵢ. Each preprocessing block PPBᵢ comprises a filter Fᵢ and a computing means EC in series. The filter Fᵢ is intended to filter the signal received in a given frequency band, denoted Bᵢ. Each filter Fᵢ is preferably chosen to be such that the passband of F1 is substantially adjacent to that of F2, and so forth, with or without overlap. Preferably, the band Bᵢ₊₁ has frequencies which are higher than those of the band Bᵢ. For a speech signal, the filters F₁ to F_{W} may be chosen, for example, to be such that F₁=[1200 Hz-3400 Hz], F₂=[800 Hz-1500 Hz], etc. The last filter F_{W} may correspond to the overall telephone band [300 Hz-3400 Hz].

The computing member EC is intended to compute the value of the characteristic magnitude of the signal, here its energy. This energy may be computed by means of conventional estimators using, for example, the sum of the absolute values of the level of the signal for a data frame, or the sum of the square values. By way of example, using the standard L1 of the energy of a frame denoted

{xᵢ(NL+1), xᵢ(NL+2) . . . , xᵢ(NL+L)} the energy Eᵢ (N) supplied to the processing block PBi is denoted as:

$${E}_{i} ( N ) = \frac{1}{L} {\sum }_{k = 1}^{L} \vert {x}_{i} ( N * L + k ) \vert$$

where N represents the sequential number of the frame and L represents the number of samples in a data frame.

The processing block PBᵢ receives in parallel: at an input, denoted IN1, the output of the preprocessing block PPBᵢ which has computed the energy of the frames of the filtered sub-band, and the original unfiltered signal at an input IN2. The processing block PBᵢ comprises:

a control device CTRL or saturation detector for determining whether the sub-band is saturated,

a bad-frame detector AFD for determining whether the current frame comprises transmission errors,

a frame corrector FC intended to correct the detected bad frame, and

switches A1 and A2 controlled by the control device CTRL as a function of the saturation result for realizing appropriate connections between the input IN1 receiving the filtered signal obtained at the output of the preprocessing block PPBᵢ, the input IN2 receiving the original signal, the input of the bad-frame detector AFD and that of the frame corrector FC.

A first input of the control device CTRL receives the filtered signal from the preprocessing block PPBᵢ and a second optional input may receive an exterior parameter ext_par supplied, for example, by the speech decoder or the channel decoder. The determination of the saturation of the sub-band may depend on the average energy level of the frames which constitute it and which is computed by the preprocessing block PPBᵢ in this embodiment. However, the saturation detection may also depend on numerous other factors such as external information supplied by the speech decoder or the channel decoder via the exterior parameter ext_par. Indicators of the reception quality of the signal, such as the indicator referred to as RXQUAL in accordance with the GSM standard, may be particularly used. The history of the signal may also be used by the control device CTRL for determining the saturation of the signal in a given band, provided that it is memorized by the control device itself or in an external memory. Several implementations are possible. They may use neuronal networks, classification by means of fuzzy logic, etc.

The operation of the processing block PBᵢ will be described hereinafter. In accordance with the value of the external parameters ext_par and the average energy of the signal in the sub-band, supplied at the input of the control device CTRL, this control device decides to either activate or deactivate the bad-frame detector AFD. It activates the bad-frame detector when the information supplied thereto at the input allow the conclusion that the sub-band is not saturated, and it deactivates the bad-frame detector when the sub-band is saturated. Indeed, in the case of a saturated context, the detection of the bad frame is not reliable. By way of example, the control device assigns the value 1 to the switches A1 and A2 for deactivating the detector AFD. In this case, the detector and the corrector FC receive nothing at the input, and the output of the processing block is directly connected to the original signal via the input IN2. In contrast, for activating the bad-frame detector, the control device assigns the value 0 to the switches for connecting the input of the bad-frame detector AFD to the filtered signal via the input IN1 and for connecting the input of the frame corrector to the original signal via the input IN2. The output of the processing block PBᵢ is connected to the output of the frame corrector.

The saturation detection preferably operates in the following manner. It depends on the context of receiving the signal. Each received frame contributes to an update of this context. A saturation factor denoted Rs(N) and determined, for example, in accordance with the following method, corresponds to each frame. The saturation level Sc(N) is first determined in the frequency sub-band Bi of the filtered signal. This determination may be carried out in numerous ways. For example, Sc(N) may be a counter which is incremented whenever the amplitude of the signal exceeds a fixed threshold in the band Bi. A less difficult implementation as regards time may be based on the energy of the frames E(N) already computed by the preprocessing block PPBᵢ. The set of levels {LG₁, . . . , LG_{K}} and a set of weights {WG₁, . . . , WG_{K}} may then be defined. Each energy E(N) corresponds to a saturation level Sc(N) defined by:

$$Sc ( N ) = {\sum }_{k = 1}^{K} I ( E ( N ) , {LG}_{k} ) {WG}_{k}$$

$$in which$$

$$I ( E ( N ) , {LG}_{k} ) = \{ \begin{matrix}1 \to E ( N ) \geq {LG}_{k} \\ 0 \to sin on\end{matrix}$$

The sign → indicates the condition in which the right-hand equation may be replaced. Whenever the energy E(N) exceeds the level LGₖ, the score Sc(N) is incremented by the penalty WGₖ. Subsequently, the saturation factor is computed as follows:

Rs(N)=βRs(N−1)+(1−β)Sc(N) with 0<β<1.

The current frame is then detected by the control device as being saturated when:

Rs(N)>Thres_sat

wherein Thres_sat corresponds to a predetermined threshold. The adaptation rate of the saturation factor Rs(N) is controlled by the parameter β. Its value may depend on the presence of a saturation context. For example, β=β1 when there is saturation and β=β2 when there is no saturation. If the energy of the signal in the band Bᵢ is less than the fixed threshold Thres_sat, the saturation factor does not necessarily have to be updated or is only updated at time intervals which are sufficiently spaced apart. In principle, the periods of silence do not transfer any information at the average level of the signal. By way of example:

If {Rs(N)>Thres_sat}

R(N+1)=βR(N)+(1−β)Sc(N)

β=β1

if not

R(N+1)=R(N)

β=β2

If no saturation is detected, the bad-frame detector is activated. Its operation relates to the detection of abnormal values of the energy of the signal by possibly taking the context of the current frame N into account. E(N) is a random value associated with the tolerance interval or range of values denoted I. In general, I is defined by the precision of the processor used. For example, for a digital signal processor DSP having 16 precision bits, I=[0; 32767] or I=[0; 65535] in accordance with the use which is made of the most significant bits. For very short time lapses representing a small number of successive frames, which is a priori the case here, the values of the magnitude E(N) which represents the energy of the current frame are comprised within tolerance values which are much more reduced and are denoted I_{C}^{N}. The analysis of the evolution of the energy in a short period of time allows detection if the energy assumes values within or outside these intervals. In the first case, the frame is said to be good (no error) and in the second case it is said to be bad (error).

This analysis may be realized, for example, by defining a short-term statistical characterization of the energy of the frames by using the probability density function or pdf, denoted P_{E}^{N}. This method also necessitates computation of the probability density function pdf. A tolerance interval denoted I_{C}^{N} based on the probability of occurrence of the energy E(N) is determined. By fixing, for example, this probability at α, one derives a value denoted T_{α}^{N} such that:

$$prob ( E ( N ) \leq {T}_{α}^{N} ) = {\int }_{0}^{{T}_{α}^{N}} {P}_{E}^{N} ( x ) dx$$

The tolerance interval is defined by I_{C}^{N}=[0; T_{α}^{N}]. When E(N)εI_{C}^{N} the current frame is said to be without error, and if not, it is said to be with error. The probability density function P_{E}^{N} depends on the time because it depends on local details of the treated frames. The interval I_{C}^{N} and the value T_{α}^{N} also depend on the time because they are derived from the quantity P_{E}^{N}.

Other methods may be used for verifying the value of the energy of the frames, such as methods based on histograms, neuronal networks, parametric analysis, etc. By way of example, a method may be based on a parametric analysis of the value T_{α}^{N} as a function of the preceding values of the energies of the frames, denoted E(N−1), . . . , E(N−P). For example, T_{α}^{N} may be dependent on a short-term average of the energy, denoted M_{E}^{N} and on a standard deviation of the energy of the frame, denoted σ_{E}^{N}. These quantities may be estimated in accordance with the following equations:

$${M}_{E}^{N} = {λ}_{1} {\sum }_{k = 1}^{P} {γ}_{1}^{k} E ( N - k )$$

$${σ}_{E}^{N} = {λ}_{2} \sqrt{{\sum }_{k = 1}^{P} {{γ}_{2}^{k} [ E ( n - k ) - {M}_{E}^{N} ]}^{2}}$$

wherein (λ₁, λ₂) and (γ₁, γ₂) are control parameters of the deviation of the estimation and the decrease of the weights given to the oldest values of the energy. P represents the length of the memory of the estimator. When T_{α}^{N}=F(M_{E}^{N}; σ_{E}^{N}) where F( ) is a function that can be predefined during a previous learning phase or estimated in line. For example, one can define T_{α}^{N}=η₁^{N}M_{E}^{N}+η₂^{N}σ_{E}^{N} where (η₁^{N}; η₂^{N}) are adjustable parameters.

When the current frame is declared to be without error by the bad-frame detector AFD, it will not be corrected. In the opposite case, the bad frame could be corrected by the frame corrector FC. Several methods are possible for performing this correction. The bad frame may be attenuated or simply replaced by silence or by comfort noise in the case where a frame comprises, for example, audio data. The recommendation GSM 06.11 (ETS 300580-3) describes a method of substituting and processing lost frames in the case of radio transmissions using a full rate speech encoder. The bad frame may also be replaced by an extrapolation of preceding frames. The frame corrector FC operates on the unfiltered original frames received at the input IN2 of the processing block PBᵢ. When a frame is detected as having an error, the subsequent frames detected without errors may also be modified for ensuring a <<comfortable>> transition between attenuated/suppressed frames and unattenuated frames.

A second embodiment referred to as parallel mode is shown in FIG. 4. The general principles are identical to those of the first mode, and the blocks having the same function are denoted by the same reference signs. In contrast, the preprocessing block, denoted //PPB operates differently. The selection of the original input signal OS in frequency sub-bands Bᵢ bounded by filters Fᵢ, as well as the computations of the energy (making use of conventional estimators) are effected in parallel for all the frequency bands Bᵢ. The result of the computations is a vector of energies. The error or bad-frame detector AFD and the control device or saturation detector CTRL operate in parallel in different frequency bands in which the input signal is filtered. The output of each detector is a vector. A supplementary decision means DB is used for deciding, on the basis of the results of the bad-frame detector AFD and the control device CTRL, whether the current frame must be corrected or not. The decision means DB may be implemented in different ways, for example, by using fuzzy logic or neuronal networks. A simple variant is to effect a correlation between the input vectors. By denoting, for example A and C as the output vectors of the bad-frame detector AFD and saturation detectors CTRL, respectively, and Aₖ and Cₖ as the components of the order of k of the vectors A and C, respectively, the detection of a bad frame in the band Bₖ may be indicated by assigning the value 1 to the component Aₖ. If not, the value 0 may be assigned to it. In contrast, when the control device or saturation detector decides to deactivate the system because of a saturation of the band Bₖ, then Cₖ=1. If not, Cₖ=0. A score S may be computed for the current frame as the scalar product of the vectors A and C:

$$S = {( A )}^{T} C = {\sum }_{k = 1}^{J} {A}_{k} {C}_{k}$$

where ( )^{T} indicates the transpose operator. The decision method performed by the decision means DB may be as follows. A reference threshold denoted Thres_gf, being fixed, if S<Thres_gf, the current frame is said to be good (without errors) and if not, it is said to be bad (with errors). In the latter case, the frame can only be corrected by the frame corrector FC, using the techniques already mentioned with reference to FIG. 3.

FIG. 5 shows an embodiment of the system according to the invention, principally constituted by a radio telephone 51, a radio base station 52 and a transmission channel 53 formed by the air, the assembly illustrating a radio transmission between the radio base station 52 and the radio telephone 51. The radio telephone 51 comprises a receiver of the type as shown in FIG. 1. Such a system allows an improvement at the receiver end of the audio reception quality of the signal received by the radio telephone.

1. A receiver for receiving, in a given frequency band, a digital signal which is formatted in successive data frames, the receiver comprising:
a filtering block for filtering the received signal in at least one frequency sub-band,
a saturation detector for detecting a saturation of the signal in one of the filtered frequency sub-bands and for supplying saturation information of said sub-band,
a bad-frame detector for detecting a transmission error in a received frame, referred to as current frame, as a function of the saturation information of the sub-band with which the current frame is associated, and for deriving a bad-frame indication.

2. A receiver as claimed in claim 1 for receiving a digital signal having a magnitude whose value has a probability which is higher than a fixed threshold to evolve, in the sequence of the frames, within a tolerance interval comprising at least a value taken during a preceding frame which has not been indicated as a bad frame by the bad-frame detector, said bad-frame detector in said receiver being provided for detecting an abnormal evolution of said value outside said tolerance interval.

3. A receiver as claimed in claim 2, wherein the saturation detection device is provided with comparison and computing means for computing an average value of said magnitude in a sub-band and for comparing it with a reference value for deriving said saturation information.

4. A receiver as claimed in claim 2, wherein the bad-frame detector comprises:
an error detector for detecting a transmission error in a frame of the sub-band and for supplying an error signal,
a decision block for receiving the saturation information of the relevant sub-band from the saturation detector, on the one hand, and the error signal from the error detector, on the other hand, for deciding that the current frame is a bad frame when the error signal indicates a transmission error and when the saturation information indicates that the sub-band is not saturated.

5. A receiver as claimed in any one of the preceding claims, wherein said magnitude is representative of an energy of the received signal.

6. A method of receiving, in a given frequency band, a digital signal which is formatted in successive data frames, the method comprising the steps of
filtering the received signal in at least one frequency sub-band,
detecting a saturation of the signal in one of the filtered frequency sub-bands and supplying saturation information of said sub-band,
bad-frame detection for detecting a transmission error in a received frame, referred to as current frame, as a function of the saturation information of the sub-band with which the current frame is associated, and for deriving a bad-frame indication.

7. A computer program product for a receiver as claimed in claim 1, comprising software code portions which, once loaded into the receiver, allow it to perform the steps of the method as claimed in claim 6.

8. A telephone for receiving digital signals from a telecommunication system, characterized in that it comprises a receiver as claimed in claim 1.

9. A telecommunication system for exchanging digital signals between at least a transmitter and a receiver, characterized in that it comprises a receiver as claimed in claim 1.
